(19) United States
(12) Patent Application Publication
(10) Pub. No.: US 2025/0393441 A1
(43) Pub. Date: Dec. 25, 2025

(54) DISPLAY DEVICE, METHOD OF MANUFACTURING THE SAME, AND ELECTRONIC DEVICE INCLUDING THE SAME

(71) Applicant: Samsung Display Co., LTD., Yongin-si (KR)

(72) Inventors: Jae Heung HA, Yongin-si (KR); Chang Yeong SONG, Yongin-si (KR); Jong Woo KIM, Yongin-si (KR)

(73) Assignee: Samsung Display Co., LTD., Yongin-si (KR)

(21) Appl. No.: 19/010,777

(22) Filed: Jan. 6, 2025

(30) Foreign Application Priority Data
Jun. 21, 2024 (KR) 10-2024-0081268
Jun. 27, 2024 (KR) 10-2024-0084259

(51) Int. Cl. H10K 59/80; H10K 59/12

(52) U.S. Cl. CPC H10K 59/873; H10K 59/1201

(57) ABSTRACT

A display device according to an embodiment may include: a first substrate defining a display area and a non-display area; a display component disposed on the first substrate that displays an image; a second substrate disposed on the display component; a filling layer disposed between the first and second substrates; and a sealing member positioned at edge portions of the first and second substrates that couples the first substrate and the second substrate. The filling layer may include a first filling layer and a second filling layer, each including different materials. The second filling layer may be spaced apart from the sealing member, with an empty space therebetween.

### CROSS-REFERENCE TO RELATED PATENT APPLICATIONS

This application claims priority to and benefits of Korean patent application number 10-2024-0081268 filed on Jun. 21, 2024 and Korean patent application number 10-2024-0084259 filed on Jun. 27, 2024 in the Korean Intellectual Property Office under 35 U.S.C. § 119, the entire disclosure of which is incorporated herein by reference.

### BACKGROUND

### 1. Technical Field

The disclosure relates to a display device, a method of manufacturing the same, and an electronic device including the display device.

### 2. Description of the Related Art

In recent years, with increasing interest in information displays, research and development of display devices has been continuously carried out.

### SUMMARY

An object of the disclosure is to provide a display device with improved reliability and a method of manufacturing the same.

A display device according to an embodiment may include: a first substrate defining a display area and a non-display area; a display component disposed on the first substrate that displays an image; a second substrate disposed on the display component; a filling layer disposed between the first and second substrates; and a sealing member positioned at edge portions of the first and second substrates that couples the first substrate and the second substrate. The filling layer may include a first filling layer and a second filling layer, each including different materials. The second filling layer may be spaced apart from the sealing member, with an empty space therebetween.

In an embodiment, each of the first and second filling layers may include a thermoset resin including a filling material, a catalyst, and a cross-linking compound, or include a UV-curable resin.

In an embodiment, the filling material may include silicon (Si), the catalyst may include platinum (Pt), and the cross-linking compound may include silicon hydride (Si—H).

In an embodiment, the second filling layer may have a content of greater than or equal to about 70% of the cross-linking compound of the first filling layer.

In an embodiment, the second filling layer may have a content of greater than or equal to about 70% of the filling material of the first filling layer.

In an embodiment, the second filling layer may have a content of greater than or equal to about 70% of the catalyst of the first filling layer.

In an embodiment, the second substrate may be a glass substrate.

In an embodiment, the empty space may be a vacuum or may be filled with gas.

In an embodiment, the display component may include: a pixel circuit layer disposed on the first substrate; a light-emitting element layer including a light-emitting element, which includes a first electrode disposed on the pixel circuit layer, a light-emitting layer disposed on the first electrode, and a second electrode disposed on the light-emitting layer; and a thin film encapsulation layer disposed between the light-emitting element layer and the filling layer.

A display device according to an embodiment may include: a first substrate defining a display area and a non-display area; a display component disposed on the first substrate that displays an image; a second substrate disposed on the display component; a filling layer disposed between the first and second substrates; and a sealing member positioned at edge portions of the first and second substrates that couples the first substrate and the second substrate. The filling layer may include a first filling layer and a second filling layer, each including a filling material, a catalyst, and a cross-linking compound. The first filling layer and the second filling layer may include different materials from each other. The second filling layer may have a content of greater than or equal to about 70% of the cross-linking compound of the first filling layer.

In an embodiment, the second filling layer may be spaced apart from the sealing member, with an empty space therebetween.

In an embodiment, the first substrate and the second substrate may be glass substrates.

The display device according to the above-described embodiment may be manufactured by a method including: preparing a first mother substrate defining a display area and a non-display area; forming a display component on a surface of the first mother substrate; applying a sealing member on the surface of the first mother substrate along an edge; applying a filling layer on a surface of a second mother substrate; bonding the surface of the first mother substrate and the surface of the second mother substrate; and separating the first and second mother substrates into display cell units. The filling layer may include a first filling layer and a second filling layer, each including different materials. The second filling layer may be spaced apart from the sealing member, with an empty space therebetween.

In an embodiment, each of the first and second filling layers may include a thermoset resin including a filling material, a catalyst, and a cross-linking compound, or may include a UV-curable resin.

In an embodiment, the filling material may include silicon (Si), the catalyst may include platinum (Pt), and the cross-linking compound may include silicon hydride (Si—H).

In an embodiment, the second filling layer may have a content of greater than or equal to about 70% of the cross-linking compound of the first filling layer.

In an embodiment, in case that applying the filling layer on the surface of the second mother substrate, the second filling layer may be applied on the surface of the second mother substrate, which overlaps an area corresponding to the display area up to about 500 μm from a boundary between the display area and the non-display area.

In an embodiment, the bonding of the surface of the first mother substrate and the surface of the second mother substrate may include irradiating a laser beam to the sealing member.

In an embodiment, the method may further include curing the filling layer after the irradiating of the laser beam to the sealing member.

In an embodiment, the applying of the filling layer on the surface of the second mother substrate may be performed using a jet dispenser.

An electronic device according to an embodiment may include: a processor configured to provide input image data to a display device; and the display device configured to display an image based on the input image data. The display device includes: a first substrate defining a display area and a non-display area; a display component disposed on the first substrate that displays an image; a second substrate disposed on the display component; a filling layer disposed between the first and second substrates; and a sealing member positioned at edge portions of the first and second substrates that couples the first substrate and the second substrate. The filling layer comprises a first filling layer and a second filling layer, each comprising different materials. The second filling layer is spaced apart from the sealing member, with an empty space therebetween.

According to an embodiment of a display device, a filling layer may be disposed between the first substrate (or display substrate) and the second substrate (or encapsulation substrate). The filling layer may include a first filling layer, positioned in a first area of the second substrate overlapping a display area of the first substrate, and a second filling layer, adjacent to the first filling layer, including a different material than the first filling layer. This arrangement may reduce or prevent defects, such as tearing in the outer part of the display panel, caused by spreadability deviations of the components in the filling layer across the middle and outer areas of the display area, thereby improving the reliability of the display device.

The effects of embodiments are not limited to the examples provided and encompass a broader range of effects as described in this specification.

### BRIEF DESCRIPTION OF THE DRAWINGS

FIG. 1 is a schematic perspective diagram illustrating a display device according to an embodiment.

FIG. 2 is a schematic cross-sectional diagram illustrating a display panel according to an embodiment.

FIG. 3 is a schematic cross-sectional diagram illustrating the display panel of FIG. 1.

FIG. 4 is a schematic block diagram illustrating an embodiment of the sub-pixels of FIG. 2.

FIG. 5 is a schematic plan view illustrating the pixels of FIG. 2.

FIG. 6 is a schematic cross-sectional diagram taken along the line II to II′ of FIG. 5.

FIG. 7 is a schematic cross-sectional diagram taken along the line I to I′ of FIG. 2.

FIG. 8 is a schematic block diagram illustrating a method of manufacturing a display device according to an embodiment.

FIGS. 9 to 19 are schematic plan views and cross-sectional diagrams illustrating process steps of a method of manufacturing a display device according to an embodiment.

FIG. 20 is a schematic block diagram illustrating an electronic device in accordance with an embodiment.

FIG. 21 is a schematic diagram illustrating an example where the electronic device of FIG. 20 is implemented as a smartphone.

FIG. 22 is a schematic diagram illustrating an example where the electronic device of FIG. 20 is implemented as a tablet computer.

### DETAILED DESCRIPTION

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art. Various embodiments do not have to be exclusive nor limit the disclosure. For example, specific shapes, configurations, and characteristics of an embodiment may be used or implemented in another embodiment.

In the drawings, sizes, thicknesses, ratios, and dimensions of the elements may be exaggerated for ease of description and for clarity. Like reference numbers and/or reference characters refer to like elements throughout.

It will be understood that, although the terms “first,” “second,” etc. may be used herein to describe various elements, these elements should not be limited by these terms. These terms are only used to distinguish one element from another. For example, a first element may be referred to as a second element, and similarly, a second element may be referred to as a first element without departing from the scope of the disclosure.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

The phrase “in a plan view” means viewing the object from the top, and the phrase “in a schematic cross-sectional view” means viewing a cross-section of which the object is vertically cut from the side. Hence, the expression “in a plan view” used herein may mean that an object is viewed in the third z direction from the top. The phrase “in a schematic cross-sectional view” means viewing a cross-section in the first x direction or the second y direction of which the object is vertically cut from the side. The third z direction also can be referred to as a “thickness direction.”

Further, throughout the specification, the word “on” a target element will be understood to mean positioned above or below the target element, and will not necessarily be understood to mean positioned “at an upper side” based on an opposite to gravity direction.

When an element, such as a layer, a region, a portion, or the like, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical and/or electrical connection, with or without intervening elements.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

As used herein, the singular forms “a,” “an,” and “the” are intended to include the plural forms as well, unless the context clearly indicates otherwise.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the disclosure and other details necessary for those skilled in the art to easily understand the disclosure will be explained in detail with reference to the accompanying drawings.

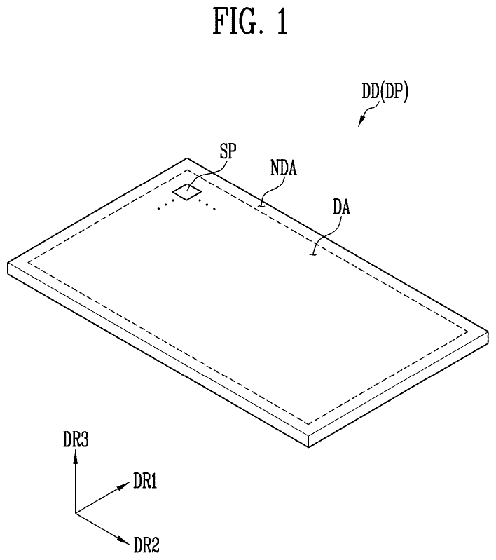

FIG. 1 is a schematic perspective diagram illustrating a display device DD according to an embodiment. In FIG. 1, for convenience, the structure of the display device DD, including, for example, a display panel DP provided in the display device DD, is briefly illustrated, focusing on a display area DA on which an image is displayed.

Referring to FIG. 1, the display device DD may display an image. The display device DD may refer to any electronic device that provides a display surface. For example, the display device DD may include, but is not limited to, televisions, laptop computers, monitors, billboards, Internet of Things (IoT) devices, mobile phones, smart phones, tablet PCS, electronic watches, smart watches, watch phones, head-mounted displays, mobile communication terminals, electronic notebooks, e-books, portable multimedia players (PMPs), navigation devices, game consoles, digital cameras, and camcorders that provide display surfaces.

The display device DD may be a flat display, a flexible display, a curved display, a foldable display, a bendable display, or a rollable display. The display device DD may also be applied to transparent display devices, head-mounted display devices, wearable display devices, etc.

The display device DD may include a display panel DP that provides the display surface. Examples of the display panel DP may include, but are not limited to, inorganic light-emitting display panels, organic light-emitting display panels, quantum dot light-emitting display panels, plasma display panels, and field emission display panels. The following describes an embodiment in which an organic light-emitting diode display panel is used as an example of the display panel DP, but the disclosure is not limited to this, and the same technical concept may be applied to other display panels where applicable.

The shape of the display device DD may vary. For example, a display device DD may have different shapes, such as rectangles, squares, squares with rounded corners (or vertices), other polygons, circles, and the like. The shape of the display area DA of the display device DD may correspond to the overall shape of the display device DD. In FIG. 1, the display device DD and the display area DA are illustrated as rectangular.

The display device DD may include the display area DA and a non-display area NDA. The display area DA may refer to an area where an image is displayed, while the non-display area NDA may refer to an area where an image is not displayed. The display area DA may also be referred to as an active area and the non-display area NDA may be referred to as an inactive area. The display area DA may be located in the center of the display device DD, but is not limited to this arrangement.

The display area DA may be an area where sub-pixels SP (or pixels) are provided. A sub-pixel SP may include at least one light-emitting element. For example, a light-emitting element may include a light-emitting layer (e.g., an organic light-emitting layer). A part emitted by a light-emitting element may be defined as a light-emitting area. The display device DD may display an image on the display area DA by driving sub-pixels SP in response to image data.

The non-display area NDA may be an area provided in the vicinity of the display area DA. In embodiments, the non-display area NDA may refer to the rest of the area on the display panel DP except the display area DA. For example, the non-display area NDA may include a wiring area, a pad area, and a dummy area.

In FIG. 1 and the drawings below, a first direction DR1, a second direction DR2, and a third direction DR3 are shown, and the directions indicated by the first direction DR1, the second direction DR2, and the third direction DR3 described in the specification are relative concepts and may correspond to different directions. In this specification, the first direction DR1 and the second direction DR2 may be orthogonal to each other, and the third direction DR3 may be a normal direction to a plane defined by the first direction DR1 and the second direction DR2, but are not limited thereto.

The thickness direction of the display device DD may be parallel to the third direction DR3, which is the normal direction to the plane defined by the first direction DR1 and the second direction DR2. In this specification, the front surface (or top surface) and back surface (or bottom surface) of the components forming the display device DD may be defined based on the third direction DR3.

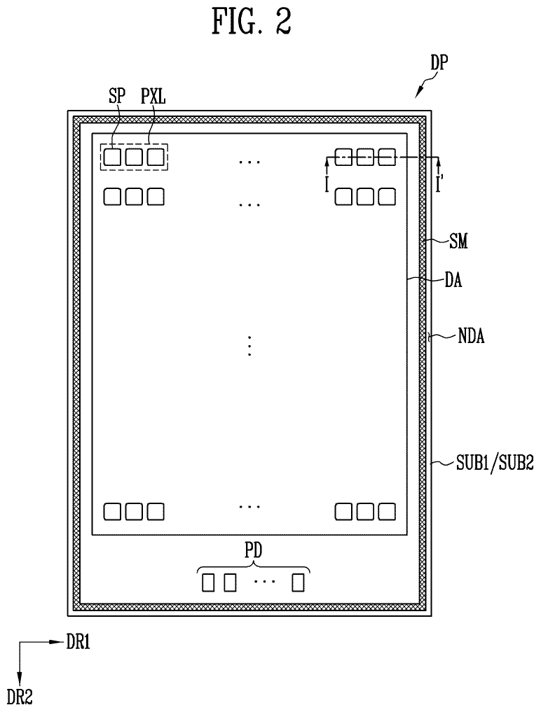

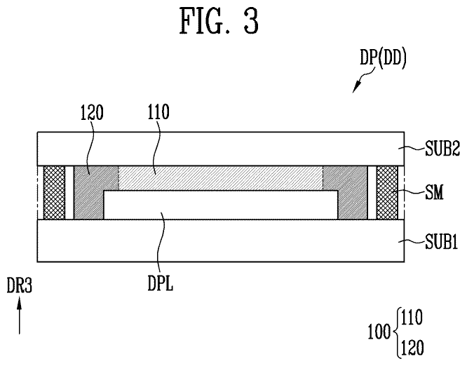

FIG. 2 is a schematic cross-sectional diagram illustrating a display panel according to an embodiment, and FIG. 3 is a schematic cross-sectional diagram illustrating the display panel of FIG. 1.

Referring to FIGS. 1 to 3, the display panel DP (or display device DD) according to an embodiment may include a first substrate SUB1, a display element layer DPL, a second substrate SUB2, a filling layer 100, and a sealing member SM. The sealing member SM may combine the first substrate SUB1 with the second substrate SUB2. Each of the first substrate SUB1 and the second substrate SUB2 may include the display area DA and the non-display area NDA.

The first substrate SUB1 may serve as the basis of the display panel DP. The first substrate SUB1 may be made of rigid materials. For example, the first substrate SUB1 may include glass, but is not limited to this material. In embodiments, the first substrate SUB1 may include quartz.

A display element layer DPL may be disposed on a surface in the third direction DR3 of the first substrate SUB1 (hereinafter, referred to as the “upper surface”).

The display element layer DPL (or display component) may display an image, thereby defining the display area DA of the display panel DP. For example, the area where the display element layer DPL is disposed on the first substrate SUB1 may be the display area DA, and the area where the display element layer DPL is not disposed may be the non-display area NDA. The display element layer DPL may overlap the display area DA in the third direction DR3 and may not overlap the non-display area NDA in the third direction DR3.

The display element layer DPL may include elements and circuits for displaying an image, such as a pixel circuit, for example, a switching element, and a light-emitting element electrically connected to the pixel circuit. The pixel circuit and the light-emitting element may form a sub-pixel SPX.

The display panel DP may include sub-pixels SP. The sub-pixels SP may be disposed in the display area DA on the first substrate SUB1. The sub-pixels SPs may be arranged in a matrix form along the first direction DR1 and the second direction DR2, which intersects the first direction DR1, but the arrangement of the sub-pixels SP is not limited to this example. For example, the sub-pixels SP may be arranged in a zigzag pattern along the first direction DR1 and the second direction DR2. For example, the sub-pixels SP may be arranged in a pentile (PENTILE™) form. The first direction DR1 may correspond to a row direction, and the second direction DR2 may correspond to a column direction. Two or more sub-pixels SP from multiple sub-pixels SPs may form a single pixel PXL.

Pads PD may be disposed in the non-display area NDA on the first substrate SUB1. The pads PD may be electrically connected to the sub-pixels SP via wirings. The pads PD may interface the display panel DP with other components of the display device DD.

A second substrate SUB2 may be disposed on the display element layer DPL. The second substrate SUB2 may serve as an encapsulation substrate to protect the display element layer DPL. The second substrate SUB2 may face the first substrate SUB1. The second substrate SUB2 may be a rigid glass substrate. The second substrate SUB2 may have a substantially constant refractive index in a visible wavelength range.

In the non-display area NDA, a sealing member SM may be disposed between the first substrate SUB1 and the second substrate SUB2. The sealing member SM may be disposed along the edge of the first substrate SUB1 and the second substrate SUB2 in the non-display area NDA to surround the display area DA in a plan view. The first substrate SUB1 and the second substrate SUB2 may be coupled by the sealing member SM. In embodiments, the sealing member SM may be made of inorganic or organic materials. For example, the sealing member SM may include, but is not limited to, inorganic materials such as frit or organic materials such as epoxy resin.

In the display area DA, a filling layer 100 may be disposed between the first substrate SUB1 and the second substrate SUB2. The filling layer 100 may act as a buffer against external pressure and the like, applied to the display panel DP, but is not limited to this function. The filling layer 100 may maintain a gap between the first substrate SUB1 and the second substrate SUB2. The filling layer 100 extends into the non-display area NDA between the first substrate SUB1 and the second substrate SUB2 and may be spaced apart from the sealing member SM, with an empty space between them. The empty space, not occupied by liquid or solid material, may be vacuumed, filled with air, or filled with other gases, but is not limited thereto.

The filling layer 100 may include a material capable of transmitting light. For example, the filling layer 100 may include an organic material such as a silicone-based resin, an epoxy-acrylic resin, or the like. The filling layer 100 may include a material suitable for refractive index matching. In embodiments, the filling layer 100 may include a first filling layer 110 and a second filling layer 120. The first filling layer 110 and the second filling layer 120 may include different materials. The filling layer 100 will be described in detail later.

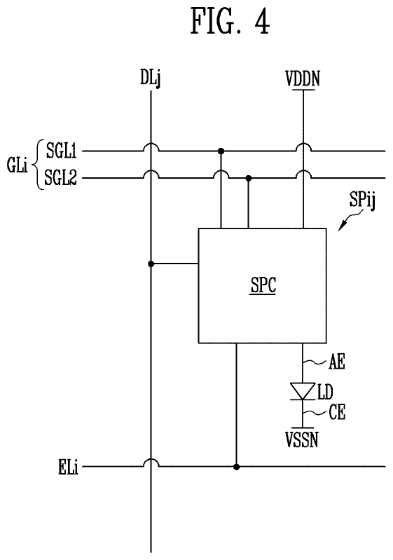

FIG. 4 is a schematic block diagram illustrating an embodiment of sub-pixels from FIG. 2. FIG. 4 illustrates sub-pixels SPij arranged in row i (where i is greater than or equal to 1 and less than or equal to m) and column j (where j is greater than or equal to 1 and less than or equal to n) among the sub-pixels SP of FIG. 2.

Referring to FIGS. 2 and 4, each sub-pixel SPij may include a sub-pixel circuit SPC and a light-emitting element LD.

The light-emitting element LD may be connected between a first power supply voltage node VDDN and a second power supply voltage node VSSN. The first power supply voltage node VDDN may transmit a first power supply voltage, and the second power voltage node VSSN may transmit a second power supply voltage. The first power supply voltage may have a relatively high voltage level, and the second power supply voltage may have a lower voltage level than the first power supply voltage.

The anode electrode AE of the light-emitting element LD may be connected to the first power supply voltage node VDDN via a sub-pixel circuit SPC, and the cathode electrode CE of the light-emitting element LD may be connected to the second power supply voltage node VSSN. For example, the anode electrode AE of the light-emitting element LD may be connected to the first power supply voltage node VDDN via one or more transistors included in the sub-pixel circuit SPC.

The sub-pixel circuit SPC may be electrically connected to signal lines. For example, the sub-pixel circuit SPC may be electrically connected to an i-th gate line GLi among gate lines, an i-th light-emitting control line ELi among the light-emitting control lines, and a j-th data line Dj among the data lines. The sub-pixel circuit SPC may control the light-emitting element LD according to signals received through these signal lines.

The sub-pixel circuit SPC may operate in response to a gate signal received through the i-th gate line GLi. The i-th gate line GLi may include one or more sub-gate lines. In some embodiments, as shown in FIG. 4, in case that the i-th gate line GLi includes two or more sub-gate lines, the sub-pixel circuit SPC may operate in response to gate signals received through the corresponding sub-gate lines.

The sub-pixel circuit SPC may operate in response to the light-emitting control signal received through the i-th light-emitting control line ELi. In some embodiments, the i-th light-emitting control line ELi may include one or more sub-light-emitting control lines. In case that the i-th light-emitting control line ELi includes two or more sub-light-emitting control lines, the sub-pixel circuit SPC may operate in response to the light-emitting control signals received through the corresponding sub-light-emitting control lines.

The sub-pixel circuit SPC may receive data signals through the j-th data line DLj. The sub-pixel circuit SPC may respond to at least one of the gate signals received through the first and second sub-gate lines SGL1 and SGL2 and store voltage corresponding to the data signal. The sub-pixel circuit SPC may regulate the current flowing from the first power supply voltage node VDDN to the second power supply voltage node VSSN through the light-emitting element LD, depending on the stored voltage, in response to the light-emitting control signal received through the i-th light-emitting control line ELi. Accordingly, the light-emitting element LD may generate light with brightness corresponding to the data signal.

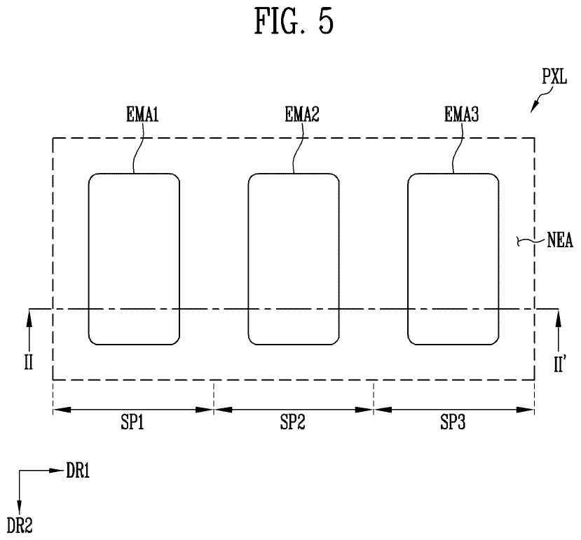

FIG. 5 is a schematic plan diagram illustrating the pixels of FIG. 2.

Referring to FIGS. 2 and 5, a pixel PXL may include a first sub-pixel SP1, a second sub-pixel SP2, and a third sub-pixel SP3, which may be arranged in a first direction DR1.

The first sub-pixel SP1 may include a first light-emitting area EMA1 and a non-light-emitting area NEA surrounding the first light-emitting area EMA1. The second sub-pixel SP2 may include a second light-emitting area EMA2 and a non-light-emitting area NEA surrounding the second light-emitting area EMA2. The third sub-pixel SP3 may include a third light-emitting area EMA3 and a non-light-emitting area NEA surrounding the third light-emitting area EMA3.

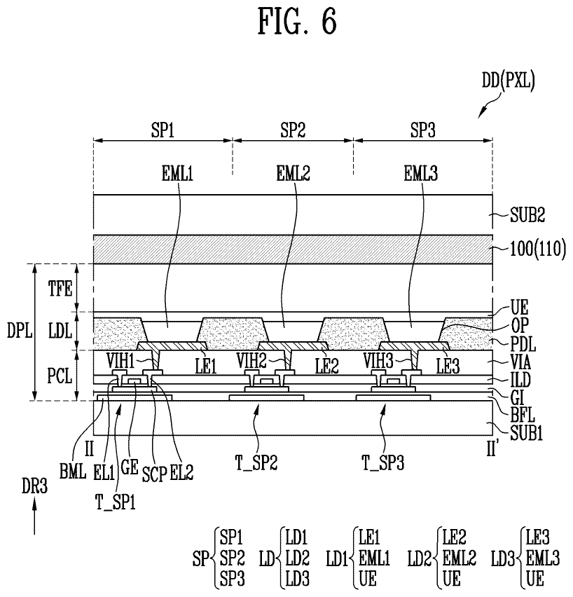

The first light-emitting area EMA1 may be an area where light is emitted from the light-emitting layer corresponding to the first sub-pixel SP1. The second light-emitting area EMA2 may be an area where light is emitted from the light-emitting layer corresponding to the second sub-pixel SP2. The third light-emitting area EMA3 may be an area where light is emitted from the light-emitting layer corresponding to the third sub-pixel SP3. Each light-emitting area may be understood as an opening (see “OP” in FIG. 6) of the pixel defining layer corresponding to each of the first to third sub-pixels SP1 to SP3.

The first sub-pixel SP1, the second sub-pixel SP2, and the third sub-pixel SP3 may have substantially the same area, but are not limited to this configuration. In some embodiments, the second sub-pixel SP2 may have an area larger than the first sub-pixel SP1, and the third sub-pixel SP3 may have an area larger than the second sub-pixel SP2.

The first sub-pixel SP1, the second sub-pixel SP2, and the third sub-pixel SP3 may have a polygonal shape. For example, the first sub-pixel SP1, the second sub-pixel SP2, and the third sub-pixel SP3 may have a rectangular or hexagonal shape, but are not limited to these shapes. In some embodiments, the first sub-pixel SP1, the second sub-pixel SP2, and the third sub-pixel SP3 may have a circular shape, a semi-elliptic shape, and the like.

The arrangement of the sub-pixels shown in FIG. 5 is illustrative, and embodiments are not limited to this example. Each pixel PXL may include two or more sub-pixels, and the sub-pixels may be arranged in various ways. Each of the sub-pixels may have a variety of shapes, and each of the light-emitting areas of the sub-pixels may also have a variety of shapes.

FIG. 6 is a schematic cross-sectional diagram taken along the line II to II′ of FIG. 5.

In FIG. 6, for the convenience of explanation, the cross-sectional structure (or stacked structure) of the display device DD is briefly illustrated, focusing on the pixels PXL included in the display device DD. The thickness direction of each of the first and second substrates SUB1 and SUB2 is indicated as the third direction DR3.

Referring to FIGS. 5 and 6, the display device DD may include at least one pixel PXL disposed in the display area (see “DA” in FIG. 2). The pixel PXL may be provided in the display area DA.

A pixel PXL may include at least one sub-pixel SP. For example, a pixel PXL may include a first sub-pixel SP1, a second sub-pixel SP2, and a third sub-pixel SP3. In some embodiments, the first sub-pixel SP1 may be a red sub-pixel, the second sub-pixel SP2 may be a green sub-pixel, and the third sub-pixel SP3 may be a blue sub-pixel, but are not limited thereto. Hereinafter, the first sub-pixel SP1, the second sub-pixel SP2, and the third sub-pixel SP3 are collectively referred to as sub-pixel SP and/or sub-pixels SP.

Each of the first to third sub-pixels SP1 to SP3 may include a first substrate SUB1, a display element layer DPL, and a second substrate SUB2. A filling layer 100 may be disposed between the first substrate SUB1 and the second substrate SUB2.

The first substrate SUB1 may include a transparent insulating material and be capable of transmitting light. The first substrate SUB1 may be a rigid substrate.

The display element layer DPL (or display component) may be disposed on the top surface of the first substrate SUB1. The display element layer DPL may include a pixel circuit layer PCL, a light-emitting element layer LDL, a thin film encapsulation layer TFE. The pixel circuit layer PCL and the light-emitting element layer LDL may be disposed to overlap on the top surface of the first substrate SUB1.

At least one insulating layer may be disposed on the pixel circuit layer PCL. As an example, the insulating layer may include a buffer layer BFL, a gate insulating layer GI, an interlayer insulating layer ILD, and a via layer VIA, sequentially stacked on the top surface of the first substrate SUB1 along the third direction DR3. The insulating layers disposed on the pixel circuit layer PCL are not limited to the embodiment described above, and other insulation layers may be added, or some insulation layers may be omitted.

The buffer layer BFL may be fully disposed on the first substrate SUB1. The buffer layer BFL may prevent the diffusion of impurities into circuit elements (or drive elements that form the sub-pixel circuit (see “SPC” in FIG. 4), for example, transistors. The buffer layer BFL may be an inorganic insulating film including an inorganic material. The buffer layer BFL may include at least one of silicon nitride (SiNₓ), silicon oxide (SiOₓ), silicon oxynitride (SiOₓN_{y}), and aluminum oxide (AlOₓ). The buffer layer BFL may be provided as a single film or as a multilayer including two or more layers. In case that the buffer layer BFL is provided as a multilayer, each layer may include a same material or different materials. The buffer layer BFL may be omitted depending on the substrate material and process conditions.

The gate insulating layer GI may be disposed entirely on the buffer layer BFL. The gate insulating layer GI and the buffer layer BFL may include a same material or may include one or more suitable (or selected) materials mentioned as constituents of the buffer layer BFL. For example, the gate insulating layer GI may be an inorganic insulating film including an inorganic material.

The interlayer insulating layer ILD may be provided and/or formed entirely on the gate insulating layer GI. The interlayer insulating layer ILD and the buffer layer BFL may include a same material or may include one or more suitable (or selected) materials mentioned as constituents of the buffer layer BFL.

The via layer VIA may be provided and/or formed entirely on the interlayer insulating layer ILD. The via layer VIA may be an inorganic insulating film including an inorganic material or an organic insulating film including an organic material. The inorganic insulating film may include, for example, at least one of silicon oxide (SiOₓ), silicon nitride (SiNₓ), silicon oxynitride (SiOₓN_{y}), and aluminum oxide (AlOₓ). The organic insulating film may include, for example, at least one of acrylic resins, epoxy resins, phenolic resins, polyamide resins, polyimide resins, unsaturated polyester resins, polyphenylene ether resins, polyphenylene sulfide resins, and benzocyclobutene resins. In some embodiments, the via layer VIA may be an organic insulating film including an organic material.

The via layer VIA may be partially opened to include a via hole. The via hole may be a connection point for electrically connecting the sub-pixel circuit SPC of each sub-pixel SP to the light-emitting element LD.

Circuit elements (or driving elements) of each of the first to third sub-pixels SP1 to SP3 may be disposed on the pixel circuit layer PCL. For example, a transistor T_SP1 of the first sub-pixel SP1, a transistor T_SP2 of the second sub-pixel SP2, and a transistor T_SP3 of the third sub-pixel SP3 may be disposed on the pixel circuit layer PCL. The transistor T_SP1 of the first sub-pixel SP1 may be one of the transistors included in the sub-pixel circuit SPC of the first sub-pixel SP1, the transistor T_SP2 of the second sub-pixel SP2 may be one of the transistors included in the sub-pixel circuit SPC of the second sub-pixel SP2, and the transistor T_SP3 of the third sub-pixel SP3 may be one of the transistors included in the sub-pixel circuit SPC of the third sub-pixel SP3. In FIG. 6, for a clear and concise explanation, one of the transistors of each sub-pixel SP is illustrated, omitting the remaining circuit elements.

The transistor T_SP1 of the first sub-pixel SP1 may include a semiconductor pattern SCP, a gate electrode GE, a first terminal EL1, and a second terminal EL2.

The gate electrode GE may be disposed on the gate insulating layer GI and covered by the interlayer insulating layer ILD. For example, the gate electrode GE may be a gate conductive layer that is disposed between the gate insulating layer GI and the interlayer insulating layer ILD. The gate electrode GE may overlap a portion of the semiconductor pattern SCP. For example, the gate electrode GE may overlap the active pattern of a semiconductor pattern SCP.

The semiconductor pattern SCP may be provided and/or formed on the buffer layer BFL. The semiconductor pattern SCP may be a semiconductor layer including polysilicon, amorphous silicon, an oxide semiconductor, etc. The semiconductor pattern SCP may include an active pattern, a first contact area, and a second contact area. The active pattern, the first contact area, and the second contact area may include a semiconductor layer which is either doped or undoped with impurities. For example, the first and second contact areas may include impurity-doped semiconductor layers, while the active pattern may include impurity-undoped semiconductor layers. The active pattern may be an area doped at a lower concentration than the first and second contact areas. Accordingly, the conductivity of the first and second contact areas may be greater than that of the active pattern. The first and second contact areas may serve as the source/drain area (or source/drain electrode) of the transistor T_SP1 of the first sub-pixel SP1.

The active pattern of the semiconductor pattern SCP is an area that overlaps the gate electrode GE and may serve as a channel area. The first contact area of the semiconductor pattern SCP may be connected to one end of the active pattern and electrically connected to the first terminal EL1. The second contact area of the semiconductor pattern SCP may be connected to the other end of the active pattern and electrically connected to the second terminal EL2.

The first terminal EL1 may be provided and/or formed on the interlayer insulating layer ILD. For example, the first terminal EL1 may include a source-drain conductive layer formed between the interlayer insulating layer ILD and the via layer VIA. The first terminal EL1 may contact the first contact area of the semiconductor pattern SCP through a contact hole that penetrates the gate insulating layer GI and the interlayer insulating layer ILD.

The second terminal EL2 may be provided and/or formed on the interlayer insulating layer ILD and may be spaced apart from the first terminal EL1. The second terminal EL2 may include a source-drain conductive layer formed between the interlayer insulating layer ILD and the via layer VIA. The second terminal EL2 may contact the second contact area of the semiconductor pattern SCP through another contact hole that penetrates the gate insulating layer GI and the interlayer insulating layer ILD.

According to embodiments, a lower metal pattern BML may be disposed under the transistor T_SP1 of the first sub-pixel SP1 described above.

The lower metal pattern BML may be a conductive layer located between the first substrate SUB1 and the buffer layer BFL. According to embodiments, the lower metal pattern BML may be electrically connected to the transistor T_SP1 of the first sub-pixel SP1 to increase the driving range of the voltage supplied to the gate electrode GE.

As the gate electrode GE, the first terminal EL1, and the second terminal EL2 are electrically connected to other circuit elements and/or wirings, the transistor T_SP1 of the first sub-pixel SP1 may be provided as one of the transistors that form the sub-pixel circuit SPC of the first sub-pixel SP1.

Each of the transistor T_SP2 of the second sub-pixel SP2 and the transistor T_SP3 of the third sub-pixel SP3 may be substantially identical to the transistor T_SP1 of the first sub-pixel SP1.

As described above, the pixel circuit layer PCL may include circuit elements for each of the first to third sub-pixels SP1 to SP3.

A light-emitting element layer LDL may be disposed on the pixel circuit layer PCL. The light-emitting element layer LDL may include a light-emitting element LD and a pixel defining layer PDL. The light-emitting element LD may include a lower electrode, a light-emitting layer, and an upper electrode UE. A light-emitting element LD may be provided for each of the first to third sub-pixels SP1 to SP3. The light-emitting element LD provided for the first sub-pixel SP1 may be a first light-emitting element LD1, the light-emitting element LD provided for the second sub-pixel SP2 may be a second light-emitting element LD2, and the light-emitting element LD provided for the third sub-pixel SP3 may be a third light-emitting element LD3.

The first lower electrode LE1 may be disposed on the pixel circuit layer PCL (or via layer VIA) of the first sub-pixel SP1, the second lower electrode LE2 may be disposed on the pixel circuit layer PCL (or via layer VIA) of the second sub-pixel SP2, and the third lower electrode LE3 may be disposed on the pixel circuit layer PCL (or via layer VIA) of the third sub-pixel SP3. Each of the first to third lower electrodes LE1 to LE3 may be electrically connected to a circuit element disposed on the pixel circuit layer PCL through a via hole that penetrates the via layer VIA. For example, the first lower electrode LE1 may be electrically connected to the transistor T_SP1 of the first sub-pixel SP1 through the first via hole VIH1 that penetrates the via layer VIA, the second lower electrode LE2 may be electrically connected to the transistor T_SP2 of the second sub-pixel SP2 through the second via hole VIH2 that penetrates the via layer VIA, and the third lower electrode LE3 may be electrically connected to the transistor T_SP3 of the third sub-pixel SP3 through the third via hole VIH3 that penetrates the via layer VIA.

In some embodiments, the first lower electrode LE1, the second lower electrode LE2, and the third lower electrode LE3 may be anode electrodes. Each of the first to third lower electrodes LE1 to LE3 may have a similar shape to the first to third light-emitting areas EMA1 to EMA3 of FIG. 5 when viewed from the third direction DR3. For example, the first lower electrode LE1 may have a shape similar to the first emitting area EMA1 when viewed from the third direction DR3, the second lower electrode LE2 may have a shape similar to the second emitting area EMA2 when viewed from the third direction DR3, and the third lower electrode LE3 may have a shape similar to the third emitting area EMA3 when viewed from the third direction DR3, but are not limited to these shapes.

Each of the first to third lower electrodes LE1 to LE3 may be electrically connected to the corresponding sub-pixel circuit SPC and receive a drive current. Each of the first to third lower electrodes LE1 to LE3 may include an opaque conductive material capable of reflecting light, but is not limited thereto. In some embodiments, the first to third lower electrodes LE1 to LE3 may include a transparent conductive material.

A pixel defining layer PDL may be located on the first to third lower electrodes LE1 to LE3. The pixel defining layer PDL may include an opening OP which exposes a portion of the first lower electrode LE1, a portion of the second lower electrode LE2, and a portion of the third lower electrode LE3, respectively. A pixel defining layer PDL may be a structure that defines (or compartmentalizes) the light-emitting area of each of the first to third sub-pixels SP1 to SP3. For example, the pixel defining layer PDL may define the first light-emitting area EMA1 of the first sub-pixel SP1, the second light-emitting area EMA2 of the second sub-pixel SP2, and the third light-emitting area EMA3 of the third sub-pixel SP3.

The pixel defining layer PDL may include an organic insulating film including an organic material. Organic materials (or organic materials) may include acrylic resins, epoxy resins, phenolic resins, polyamide resins, polyimide resins, etc. In some embodiments, the pixel defining layer PDL may include a light-absorbing material, or a photo-absorbing agent may be applied to the pixel defining layer PDL to absorb light from the outside. For example, the pixel defining layer PDL may include a carbon-based black pigment. However, the embodiment is not limited thereto.

The first light-emitting layer EML1 may be disposed on the first lower electrode LE1 exposed by an opening OP of the pixel defining layer PDL, the second light-emitting layer EML2 may be disposed on the second lower electrode LE2 exposed by another opening OP of the pixel defining layer PDL, and the third light-emitting layer EML3 may be disposed on the third lower electrode LE3 exposed by another opening OP of the pixel defining layer PDL. Each of the first and third light-emitting layers EML1, EML2, and EML3 may have a multi-layer structure including a hole injection layer, a hole transport layer, an organic light-emitting layer, an electron transport layer, and an electron injection layer.

The first to third light-emitting layers EML1 to EML3 may include at least one light-emitting material emitting light of different colors corresponding to the sub-pixels SP. For example, the first light-emitting layer EML1 may include at least one light-emitting material emitting red light, the second light-emitting layer EML2 may include at least one light-emitting material emitting green light, and the third light-emitting layer EML3 may include at least one light-emitting material emitting blue light. However, embodiments are not limited thereto, and in some embodiments, each of the first to third light-emitting layers EML1 to EML3 may emit white light as a whole by stacking multiple light-emitting materials capable of generating light of different colors, such as red light, green light, blue light, and the like. A color filter may be further disposed on each of the first to third light-emitting layers EML1 to EML3. The color filter may include at least one of the following color filters: a red color filter, a green color filter, or a blue color filter.

The upper electrode UE may be disposed on the first to third light-emitting layers EML1, EML2 and EML3 and the pixel defining layer PDL. In some embodiments, the upper electrode UE may be a cathode electrode. The upper electrode UE may be a common layer provided for the first to third sub-pixels SP1 to SP3. The upper electrode UE may be provided as a plate over the entire display area DA. In some embodiments, the upper electrode UE may function as a half-mirror that partially transmits and partially reflects light emitted from the corresponding light-emitting layer.

The upper electrode UE may be a thin metal layer which is thick enough to transmit light emitted from the corresponding light-emitting layer. The upper electrode UE may be formed of a metallic material with relatively thin thickness or a transparent conductive material. In some embodiments, the upper electrode UE may include at least one of a variety of transparent conductive materials, including indium tin oxide, indium zinc oxide, indium tin zinc oxide, aluminum zinc oxide, gallium zinc oxide, zinc tin oxide, or gallium tin oxide. In another embodiment, the upper electrode UE may include at least one of magnesium, silver, and a mixture thereof. However, the material of the upper electrode UE is not limited to these examples.

The portion of the upper electrode UE overlapping the first lower electrode LE1, the first light-emitting layer EML1, and the first lower electrode LE1 may form the first light-emitting element LD1. The first lower electrode LE1 may be the first electrode of the first light-emitting element LD1, and the upper electrode UE may be the second electrode of the first light-emitting element LD1. The portion of the upper electrode UE overlapping the second lower electrode LE2, the second light-emitting layer EML2, and the second lower electrode LE2 may form the second light-emitting element LD2. The second lower electrode LE2 may be the first electrode of the second light-emitting element LD2, and the upper electrode UE may be the second electrode of the second light-emitting element LD2. The portion of the upper electrode UE overlapping the third lower electrode LE3, the third light-emitting layer EML3, and the third lower electrode LE3 may form the third light-emitting element LD3. The third lower electrode LE3 may be the first electrode of the third light-emitting element LD3, and the upper electrode UE may be the second electrode of the third light-emitting element LD3.

A thin film encapsulation layer TFE may be disposed on the upper electrode UE. The thin film encapsulation layer TFE may cover the light-emitting element layer LDL. The thin film encapsulation layer TFE may prevent oxygen and/or moisture from penetrating into the light-emitting element layer LDL. In some embodiments, the thin film encapsulation layer TFE may include a structure in which one or more inorganic films and one or more organic films are alternately stacked. For example, the inorganic film may include silicon nitride, silicon oxide, silicon oxynitride, or the like. For example, the organic film may include organic insulating materials such as acrylic resins, epoxy resins, phenolic resins, polyamide resins, polyimide resins, unsaturated polyester resins, polyphenylene resins, polyphenylene sulfide resins, or benzocyclobutene. However, the materials in the organic and inorganic films of the thin film encapsulation layer TFE are not limited to these examples.

The second substrate SUB2 may be disposed on the display element layer DPL including the above-described configurations. The second substrate SUB2 may face the first substrate SUB1 in the third direction DR3. The second substrate SUB2 may act as an encapsulation substrate that protects the display element layer DPL.

A filling layer 100 may be disposed on the display area DA between the display element layer DPL on the first substrate SUB1 and the second substrate SUB2. For example, a first filling layer 110 may be disposed on the display area DA between the first substrate SUB1 and the second substrate SUB2. The first filling layer 110 may maintain a gap between the first substrate SUB1 and the second substrate SUB2.

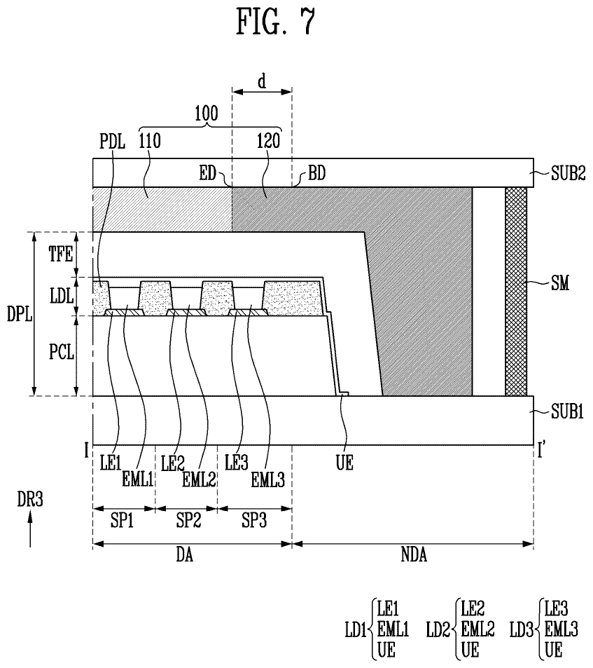

FIG. 7 is a schematic cross-sectional diagram taken along the line I to I′ of FIG. 2.

In order to avoid redundant explanations in relation to the embodiment in FIG. 7, only the differences from the above-mentioned embodiment are explained.

Referring to FIGS. 2 and 7, a display panel DP (or a display device DD) may include a first substrate SUB1 and a second substrate SUB2 joined by a sealing member SM. A display element layer DPL may be disposed on the upper surface of the first substrate SUB1. The display element layer DPL may include a pixel circuit layer PCL, a light-emitting element layer LDL, and a thin film encapsulation layer TFE.

A filling layer 100 may be disposed between the display element layer DPL on the first substrate SUB1 and the second substrate SUB2. The filling layer 100 may be formed by inkjet printing, spin coating, slit coating, jet dispensing, or screen printing, but embodiments are not limited thereto.

The filling layer 100 may be formed on a surface of the second substrate SUB2 (e.g., a surface facing the display element layer DPL of the first substrate SUB1) and may be located between the display element layer DPL and the second substrate SUB2 in the process of coupling the second substrate SUB2 with the first substrate SUB1.

The filling layer 100 may be disposed on the first substrate SUB1 and may cover the display element layer DPL. The filling layer 100 may contact the upper surface of the first substrate SUB1 and may contact the upper surface and the side surface of the display element layer DPL. The filling layer 100 may contact a surface of the second substrate SUB2 (e.g., the “lower surface”). An empty space may exist between the filling layer 100 and the sealing member SM. In order to prevent the filling layer 100 from being affected by the laser during the curing stage of the sealing member SM, the filling layer 100 and the sealing member SM may be spaced apart from each other by a distance.

The filling layer 100 may reduce the empty space or air layer between the first substrate SUB1 and the second substrate SUB2 while preventing the occurrence of voids so that a clear image may be displayed. The filling layer 100 may be formed from a material that may ensure ease of application and transparency. The filling layer 100 may include a polymer resin containing silicon. For example, the polymer resin containing silicon may include, but is not limited to, at least one of silicon-containing acrylate resins, silicon-containing epoxy resins, silicon-containing vinyl-based resins, and silicon-containing phenyl-based resins.

In some embodiments, the filling layer 100 may include a first filling layer 110 and a second filling layer 120. The first filling layer 110 may be disposed on the middle part of the display area DA of the first and second substrates SUB1 and SUB2, while the second filling layer 120 may be disposed on the outer part of the display area DA of the first and second substrates SUB1 and SUB2 and on the non-display area NDA adjacent to the outer part. The edge ED of the second filling layer 120 may be located in a selected interval d from the boundary BD between the display area DA and the non-display area NDA, towards the display area DA. The interval d may refer to a distance between the boundary BD and the edge ED of the second filling layer 120, which may be about 500 μm, but is not limited thereto. For example, the second filling layer 120 may be located between the first substrate SUB1 and the second substrate SUB2 extending from the non-display area NDA into the outer portion of the display area DA adjacent to the non-display area NDA. The second filling layer 120 may be spaced apart from the sealing member SM in the non-display area NDA.

The first filling layer 110 and the second filling layer 120 may include different materials. To prevent the occurrence of haze due to mixing, the first filling layer 110 and the second filling layer 120 may include similar components. For example, the first filling layer 110 and the second filling layer 120 may include thermoset or UV-curable resins containing silicon.

In some embodiments, each of the first filling layer 110 and the second filling layer 120 may include a filling material, a catalyst, and a cross-linking compound. For example, the filling material may include silicon (Si), the catalyst may include platinum (Pt), and the cross-linking compound may include silicon hydride (Si—H), but is not limited thereto. Here, the platinum catalyst may act as an initiator for curing during the manufacturing process of the display device DD.

The contents of the components included in the first filling layer 110 and the second filling layer 120 may differ from each other. For example, the content of the cross-linking compound included in each of the first filling layer 110 and the second filling layer 120 may vary. For example, the first filling layer 110 and the second filling layer 120 may include a same filling material content, and the first filling layer 110 and the second filling layer 120 may also include a same catalyst content. For example, the content of the cross-linking compound included in the second filling layer 120 may be greater than or equal to about 70% of the content of the cross-linking compound included in the first filling layer 110.

As another example, the content of both the filling material and cross-linking compound included in each of the first and second filling layers 120 may differ. For example, the content of the filling material included in the first filling layer 110 and the content of the filling material included in the second filling layer 120 may be different from each other, and the content of the cross-linking compound included in the first filling layer 110 and the content of the cross-linking compound included in the second filling layer 120 may be different from each other, and the content of the catalyst included in the first filling layer 110 and the content of the catalyst included in the second filling layer 120 may be identical to each other. For example, the content of the filling material included in the second filling layer 120 may be greater than or equal to about 70% of the content of the filling material included in the first filling layer 110, and the content of the cross-linking compound included in the second filling layer 120 may be greater than or equal to about 70% of the content of the cross-linking compound included in the first filling layer 110.

As another example, the contents of the filling material, the catalyst, and the cross-linking compound included in the first filling layer 110 and the second filling layer 120 may all differ. For example, the content of the filling material included in the first filling layer 110 and the content of the filling material included in the second filling layer 120 may be different from each other, and the content of the catalyst included in the first filling layer 110 and the content of the catalyst included in the second filling layer 120 may be different from each other, and the content of the cross-linking compound included in the first filling layer 110 and the content of the cross-linking compound included in the second filling layer 120 may be different from each other. For example, the content of the filling material included in the second filling layer 120 may be greater than or equal to about 70% of the content of the filling material included in the first filling layer 110, the content of the catalyst included in the second filling layer 120 may be greater than or equal to about 70% of the content of the catalyst included in the first filling layer 110, and the content of the cross-linking compound included in the second filling layer 120 may be greater than or equal to about 70% of the content of the cross-linking compound included in the first filling layer 110.

TABLE 1

| | | |
|---|---|---|
| | Comparative | |
| Filling layer material | example | Example |

| | | | |
|---|---|---|---|
| Outer/center | Filling material | 52.5% | 100% |
| area ratio | Cross-linking | 94.8% | 80.0% |
| | compound | | |

Table 1 measures the ratio of the material in the filling layer 100 applied to the outer part of the display area DA compared to the material in the filling layer 100 applied to the middle part of the display area DA for both the comparative example and the example. The comparative example may refer to a case where the same material is applied to both the middle part and the outer part of the display area DA. In contrast, the example may refer to a case where different materials are applied to the middle part and the outer part of the display area DA. As shown in the table above, in the case of the comparative example, there is a significant difference in the content of the filling material between the middle part and the outer part of the display area DA, indicating that a relatively large amount of cross-linking compounds is included in the filling layer 100 in the outer part of the display area DA. However, in the case of the example, the contents of the filling material in both the middle part and the outer part of the display area DA are the same, preventing an excessive amount of cross-linking compounds from being included in the filling layer 100 in the outer part of the display area DA.

As described above, the content of the cross-linking compound in the second filling layer 120 may differ from the content of the cross-linking compound in the first filling layer 110. In the process of coupling the first substrate SUB1 with the second substrate SUB2, the content of the cross-linking compound in the second filling layer 120 is set (or intended) to be lower than that in the first filling layer 110 in consideration of the difference in material spreadability of the filling layer 100 between the middle part of the display area DA and the outer part of the display area DA (or an area of the display area DA adjacent to the non-display area NDA).

If the filling layer 100 including a same material (or including one type of material) is disposed in both the middle and outer areas of the display area DA between the first substrate SUB1 and the second substrate SUB2, the components forming the filling layer 100, such as the filling material, the catalyst, and the cross-linking compound, may have different spreadability in the process of coupling the first substrate SUB1 with the second substrate SUB2. This may result in a difference in composition between the filling layer 100 spread in the middle part of the display area DA and the filling layer 100 spread in the outer part of the display area DA and the adjacent non-display area NDA. For example, compared to the filling layer 100 spread in the middle part of the display area DA, the filling layer 100 spread in the outer part of the display area DA and the adjacent non-display area NDA may contain lower amounts of the filling material and the catalyst, while the amount of the cross-linking compound may remain unchanged. Thus, the filling layer 100 spread in the outer part of the display area DA (or located on the outer part of the display area DA) may include a relatively larger amount of cross-linking compound than the filling layer 100 spread in the middle part of the display area DA. The first substrate SUB1 and the second substrate SUB2 may not be properly coupled in the outer part of the display area DA and the adjacent non-display area NDA, causing the second substrate SUB2 to detach and leading to tear black spot defects in the sub-pixels located in the outer part of the display area DA (see “SP” in FIG. 6).

Accordingly, in the above-described embodiment, non-coupling of the first substrate SUB1 and the second substrate SUB2 in the outer part of the display area DA may be reduced or minimized. This can be achieved by preventing a relatively large amount of cross-linking compound from being included in the filling layer 100 spread to the outer part of the display area DA compared to the filling layer 100 spread to the middle part of the display area DA. By disposing the second filling layer 120, which has a lower content of the cross-linking compound, between the first substrate SUB1 and the second substrate SUB2 in an area corresponding to the outer part of the display area DA, and disposing the first filling layer 110, which has a higher content of the cross-linking compound, in an area corresponding to the middle part of the display area DA, the bonding process between the first substrate SUB1 and the second substrate SUB2 may be improved.

Hereinafter, a method of manufacturing a display device DD according to an embodiment will be described.

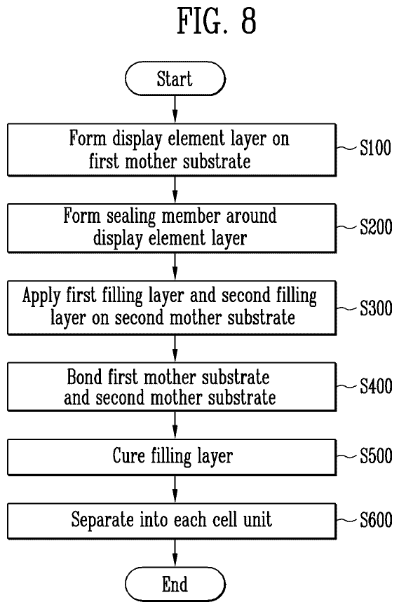

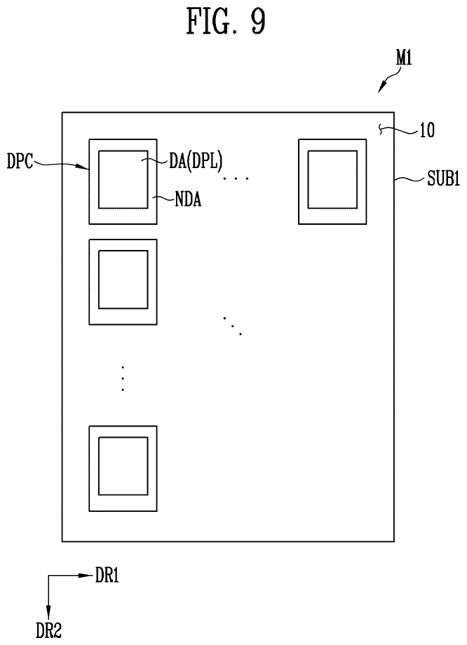

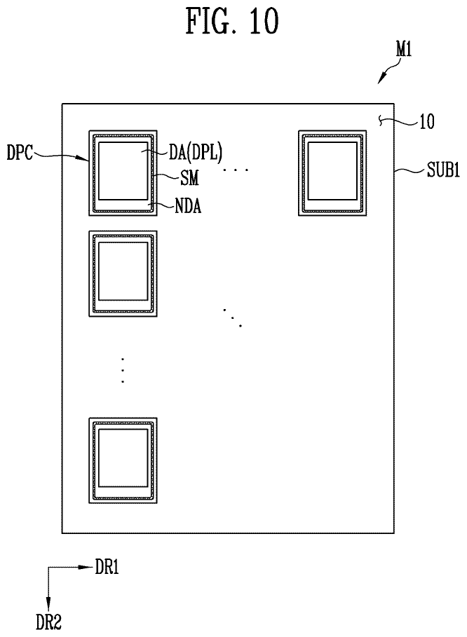

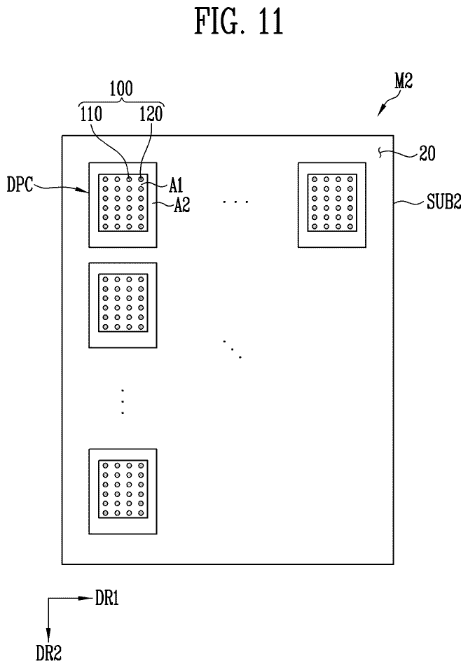

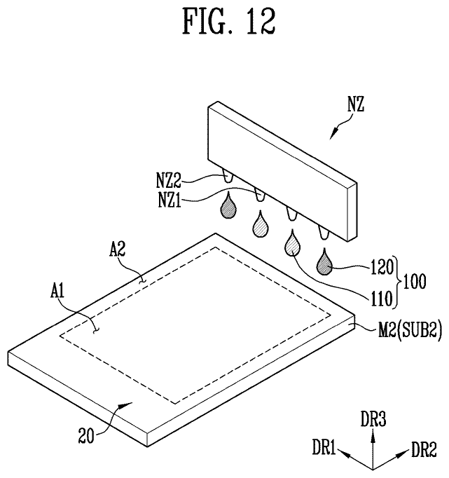

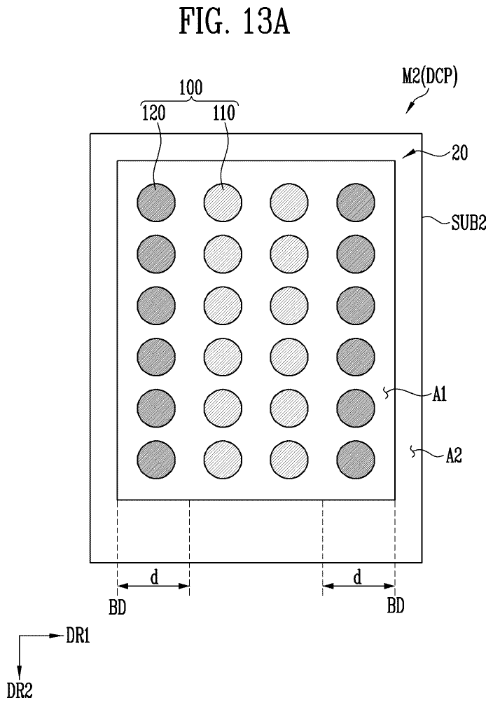

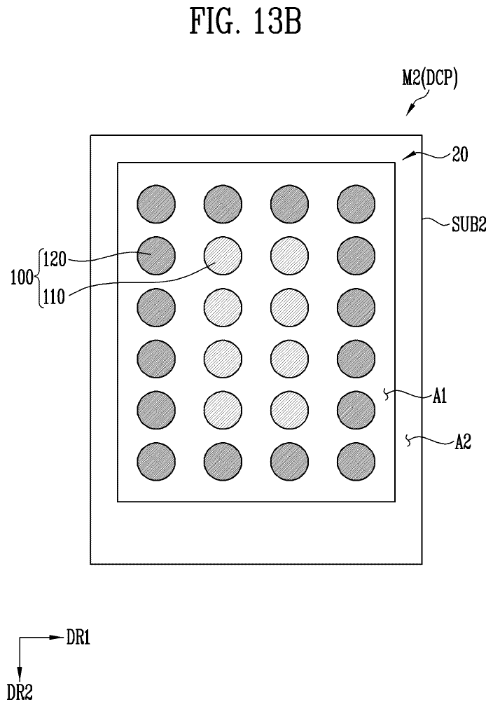

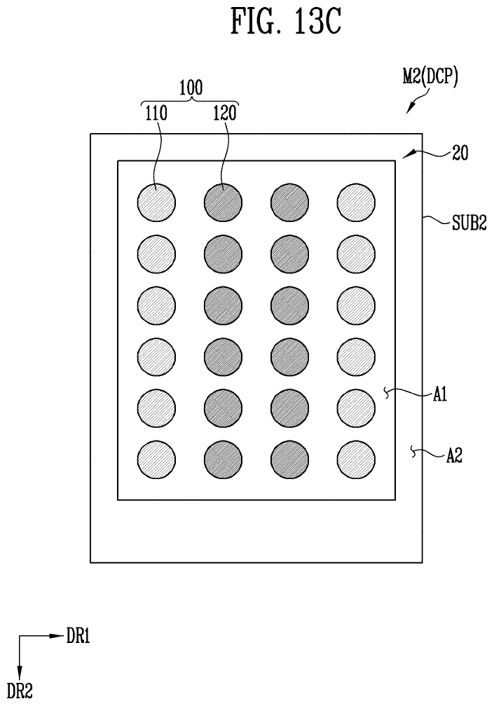

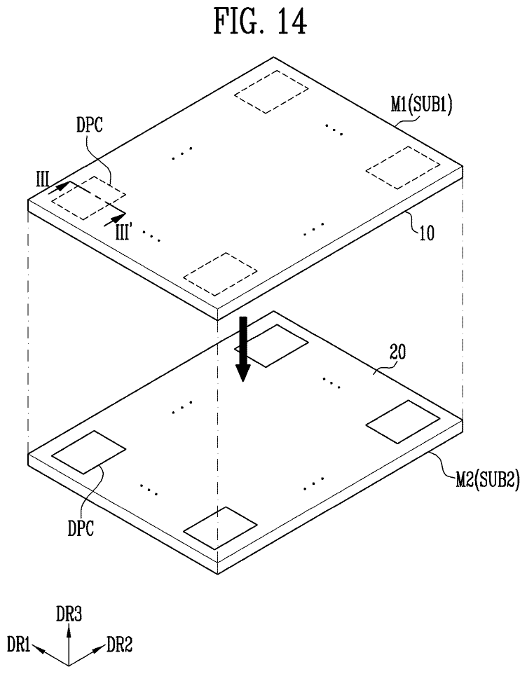

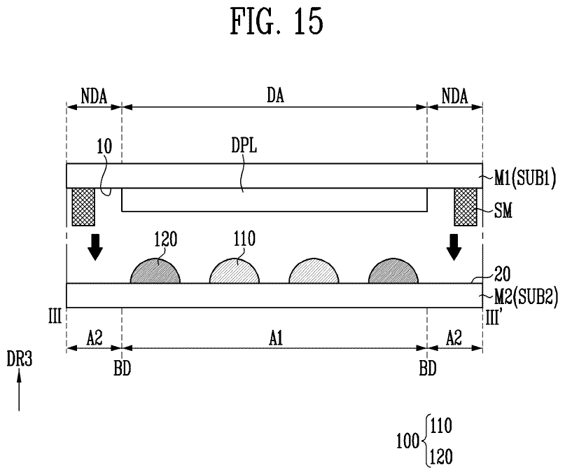

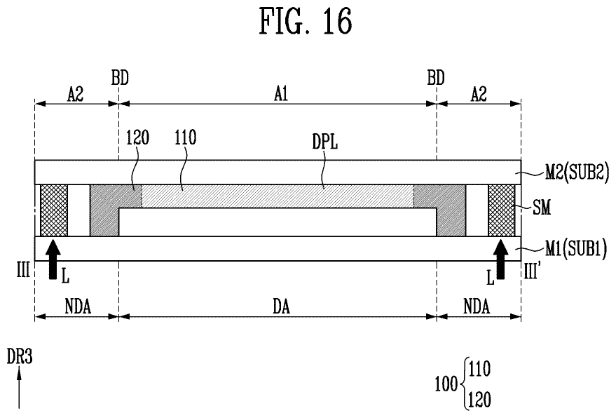

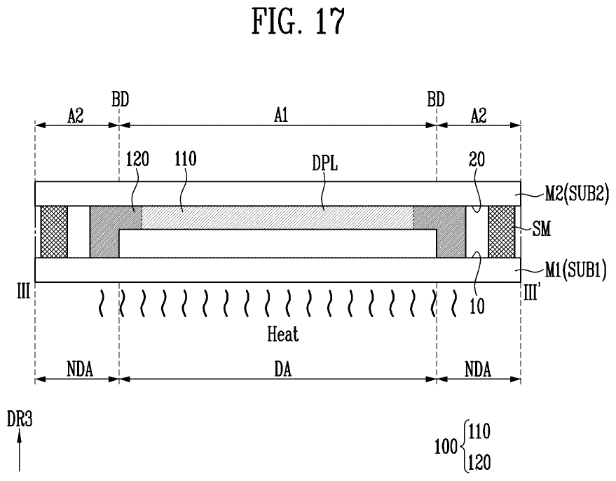

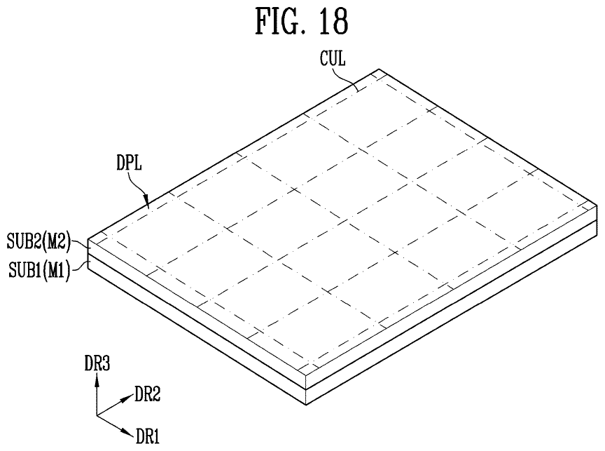

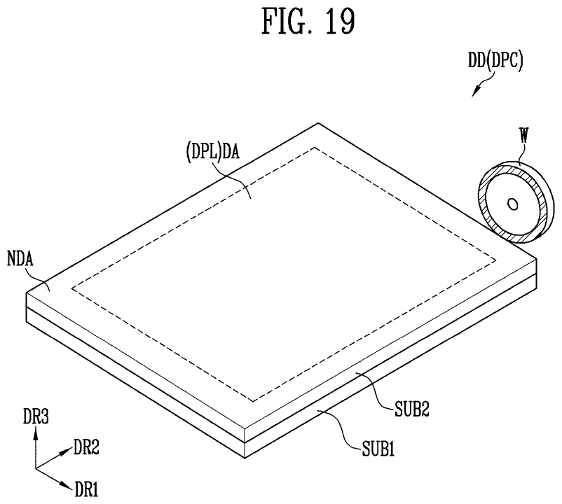

FIG. 8 is a schematic block diagram illustrating a method of manufacturing a display device according to an embodiment, and FIGS. 9 to 19 are schematic plan and cross-sectional diagrams illustrating process steps of the method. FIG. 9 is a schematic plan diagram illustrating a first mother substrate M1 for a first step S100 of FIG. 8, FIG. 10 is a schematic plan diagram illustrating a first mother substrate M1 for a second step S200 of FIG. 8, FIG. 11 is a schematic plan diagram illustrating a second mother substrate M2 for a third step S300 of FIG. 8, FIG. 12 is a schematic perspective diagram illustrating the application of the filling layer 100 to a display cell DCP of the second mother substrate M2 from FIG. 11, FIG. 13A is a schematic plan diagram illustrating a display cell DCP of the second mother substrate M2 from FIG. 11, FIGS. 13B and 13C are schematic plan diagrams illustrating modified examples of first and second filling layers from FIG. 13A, FIGS. 14 to 16 are schematic diagrams illustrating a fourth step S400 of FIG. 8, FIG. 17 is a schematic cross-sectional diagram taken along the line III to III′ of FIG. 14, illustrating a fifth step S500 of FIG. 8, and FIGS. 18 and 19 are schematic diagrams illustrating a sixth step S600 of FIG. 8.

In the embodiment shown in FIGS. 8 to 19, the manufacturing steps of the display device DD are described as being performed one after the other, but it is understood that some of the steps shown as being performed in succession may be performed at the same time, the order of each step may be altered, some steps may be omitted, or additional steps may be included between existing steps, provided the overall concept of the disclosure remains unchanged.

With respect to FIGS. 8 to 19, for the convenience of explanation, redundant descriptions will be omitted.

Referring to FIGS. 8 and 9, the first mother substrate M1 is prepared, and the display element layer DPL is formed on the upper surface 10 of the first mother substrate M1 (S100—Step 1). The display element layer DPL is as described in reference to FIGS. 6 and 7, and since various display element layers DPL may be used, the description of a specific manufacturing method is omitted.

The first mother substrate M1 is a substrate used for the simultaneous manufacture of multiple display cells DPC to facilitate the process and may serve as the first substrate SUB1 of the display device (see “DD” in FIG. 1). The first mother substrate M1 may include at least one unit area. The unit area corresponds to an individual display cell DPC (or individual display device DD), and an individual display cell DPC may be formed in each unit area.

In some embodiments, each of the display cells DPC may be individually separated and may act as a display device DD. These display cells DPC may be separated by a cutting process, and the like, after forming multiple display cells DPC at the same time on the first mother substrate M1. The display cells DPC may be arranged in multiples on the upper surface 10 of the first substrate M1 in a matrix form, with rows (or display cell rows) extending in the first direction DR1 and columns (or display cell columns) extending in the second direction DR2.

Each of the display cells DPC may include a display area DA in which the display element layer PDL is disposed, and a non-display area NDA that surrounds the display area DA.

Referring to FIGS. 8 and 10, a sealing member SM is applied along the edge of the upper surface 10 of the first mother substrate M1 (S200—Step 2).

In the drawings, the sealing member SM is shown as being formed on the upper surface 10 of the first mother substrate M1, but is not limited thereto. According to embodiments, the sealing member SM may be formed on a surface of the second mother substrate (see “M2” in FIG. 11).

Referring to FIGS. 8, 11, 12, and 13C, the second mother substrate M2 is prepared, and the first filling layer 110 and the second filling layer 120 are applied to a surface 20 of the prepared second mother substrate M2 (S300—Step 3).

The second mother substrate M2 is an encapsulation substrate coupled with the first mother substrate M1 to form multiple display cells DPC and may serve as the second substrate SUB2 of the display device DD. The second mother substrate M2 may include at least one unit area corresponding to the unit area of the first mother substrate M1. Each unit area may include a first area A1 and a second area A2. The first area A1 may correspond to the display area DA of the first mother substrate M1, and the second area A2 may correspond to the non-display area NDA of the second mother substrate M2.

The first filling layer 110 may be applied to the middle part of the first area A1 of the second mother substrate M2, while the second filling layer 120 may be applied to the outer part of the first area A1 adjacent to the second area A2 of the second mother substrate M2. For example, an uncured filling layer 100 may be applied to the first area A1 on a surface 20 of the second mother substrate M2 using the nozzle NZ of a jet dispenser. The nozzle NZ may include a first nozzle NZ1 for applying the material of the first filling layer 110 and a second nozzle NZ2 for applying the material of the second filling layer 120. The first filling layer 110 and the second filling layer 120 may include different materials.

The outer part of the first area A1 of the second mother substrate M2 on which the second filling layer 120 is applied may be an area in a selectable interval d from the boundary BD between the first area A1 (or display area DA) and the second area A2 (or non-display area NDA) toward the middle part of the first area A1. The interval d may be about 500 μm, but is not limited thereto.

In FIG. 13A, the second filling layer 120 is shown as being applied to the left and right sides of the outer part of the first area A1 of the second mother substrate M2, but is not limited thereto. In some embodiments, the second filling layer 120 may be applied to the entire outer part of the first area A1 of the second mother substrate M2, for example, the left, right, upper, and lower sides, as shown in FIG. 13B.

In the above embodiment, it is described that the first filling layer 110 is applied to the middle part of the first area A1 of the second mother substrate M2, and the second filling layer 120 is applied to the outer part of the first area A1 of the second mother substrate M2, but are not limited thereto. In other embodiments, the second filling layer 120 may be applied to the middle part of the first area A1 of the second mother substrate M2, and the first filling layer 110 may be applied to the outer part of the first area A1 of the second mother substrate M2, as shown in FIG. 13C.

Referring to FIGS. 8, 14, 15, and 16, the first mother substrate M1 and the second mother substrate M2 are bonded (S400—Step 4).

The first mother substrate M1 may be disposed so that the upper surface 10 of the first mother substrate M1 faces the upper surface 20 of the second mother substrate M2. By moving the first mother substrate M1 towards the second mother substrate M2, the first mother substrate M1 and the second mother substrate M2 may be bonded through the sealing member SM. In some embodiments, the second mother substrate M2 may be disposed so that a surface 20 of the second mother substrate M2 may face the upper part of the upper surface 10 of the first mother substrate M1.

In the process of bonding the first mother substrate M1 and the second mother substrate M2, the uncured filling layer 100 may be pressed into close contact by the first mother substrate M1 and/or the display element layer DPL formed on the first mother substrate M1. Accordingly, the uncured filling layer 100 may spread from the first area A1 toward the second area A2. The spreading of the filling layer 100 in the direction of the sealing member SM may be controlled to ensure that the filling layer 100 remains separated from the sealing member SM by adjusting the application time, speed of the filling layer 100, and the like.

Subsequently, the bonded first mother substrate M1 and second mother substrate M2, with the first mother substrate M1 located at the bottom, may be reversed up and down.

A laser beam L may be used to irradiate the sealing member SM, partially melting it to fully bond the first mother substrate M1 and the second mother substrate M2. In case that the laser beam L irradiates the sealing member SM, the filling layer 100 remains separated from the sealing member SM and does not contact the sealing member SM. Therefore, the filling layer 100 may not be affected by the thermal energy from the laser beam L or from the sealing member SM itself.

Referring to FIGS. 8 and 17, the filling layer 100 may be cured (S500—step 5).

The curing process of the filling layer 100 may be performed by heat curing, UV curing, or a combination of both heat curing and UV curing.

Referring to FIGS. 8, 18, and 19, the first and second mother substrates M1 and M2 may be separated into individual display cells DPC by irradiating a laser beam along the cutting line CUL patterned on the first and second mother substrates M1 and M2 (S600—step 6).

Each display cell DPC may implement a display device DD, which includes a first substrate SUB1 including a display element layer DPL and a second substrate SUB2 disposed on the first substrate SUB1. The display device DD may be identical to the display device DD described with reference to FIGS. 1 to 3.

After the above-described process, a scribing process may be carried out to smooth the edge portions of the individually separated display cells DPC (or display devices DD). The scribing process may involve gently polishing the sharp edge portions using a laser beam or a wheel W including a grinding machine.

After the scribing process, a chemical strengthening process may be performed on the first and second substrates SUB1 and SUB2 of each display cell DPC. Prior to the strengthening process, a cleaning process may also be performed to remove any foreign substances on the surface of the first and second substrates SUB1 and SUB2.

Separate display cells DPC may be used in a variety of electronic devices such as TVs, smartphones, wearable devices, etc. For example, these display cells DPC may be used in devices implementing virtual reality VR or augmented reality AR.

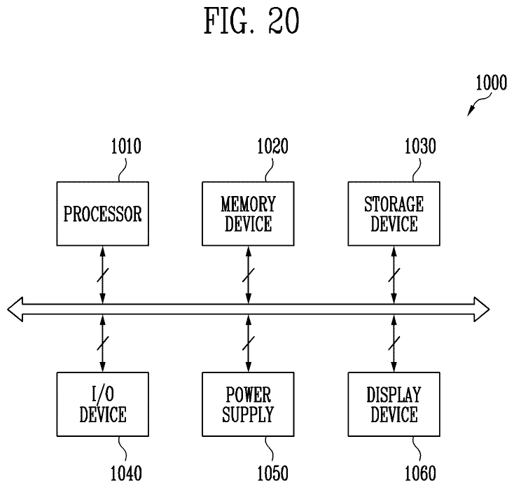

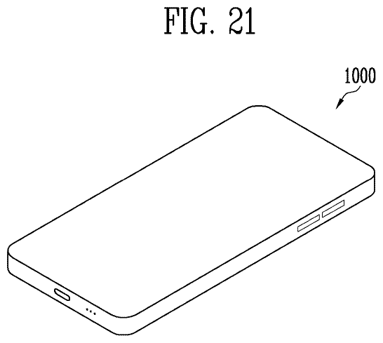

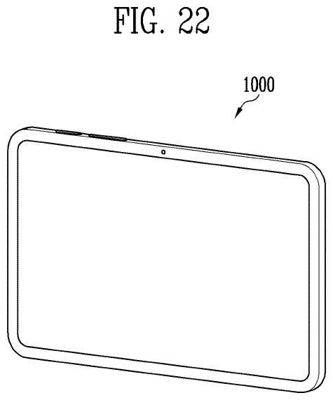

FIG. 20 is a schematic block diagram illustrating an electronic device in accordance with an embodiment. FIG. 21 is a schematic diagram illustrating an example where the electronic device of FIG. 20 is implemented as a smartphone. FIG. 22 is a schematic diagram illustrating an example where the electronic device of FIG. 20 is implemented as a tablet computer.

Referring to FIGS. 20 to 22, the electronic device 1000 may include a processor 1010, a memory device 1020, a storage device 1030, an input/output (I/O) device 1040, a power supply 1050, and a display device 1060. The display device 1060 may be the display device DD of FIG. 1. The electronic device 1000 may further include various ports for communication with a video card, a sound card, a memory card, a USB device, or other systems. In an embodiment, as illustrated in FIG. 21, the electronic device 1000 may be implemented as a smartphone. In an embodiment, as illustrated in FIG. 22, the electronic device 1000 may be implemented as a tablet computer. However, the aforementioned examples are illustrative, and the electronic device 1000 is not necessarily limited to the aforementioned examples. For example, the electronic device 1000 may be implemented as a cellular phone, a video phone, a smartpad, a smartwatch, a navigation device for vehicles, a computer monitor, a laptop computer, a head-mounted display device, or the like.

The processor 1010 may perform specific calculations or tasks. In an embodiment, the processor 1010 may be a micro processor, a central processing unit, an application processor, or the like. The processor 1010 may be connected to other components through an address bus, a control bus, a data bus, and the like. In an embodiment, the processor 1010 may be connected to an expansion bus such as a peripheral component interconnect (PCI) bus.

The memory device 1020 may store data needed to perform the operation of the electronic device 1000. For example, the memory device 1020 may include non-volatile memory devices such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, and a ferroelectric random access memory (FRAM) device, and/or volatile memory devices such as a dynamic random access memory (DRAM) device, a static random access memory (SRAM) device, a mobile DRAM device, and so on.

The storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be included in the I/O device 1040.

The power supply 1050 may supply power needed to perform the operation of the electronic device 1000. For example, the power supply 1050 may be a power management integrated circuit (PMIC).

The display device 1060 may display an image corresponding to visual information of the electronic device 1000. Here, the display device 1060 may be an organic light emitting diode (OLED) display device or a quantum dot light emitting display device, but is not necessarily limited thereto. The display device 1060 may be connected to other components through the buses or other communication links.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A display device comprising:
a first substrate defining a display area and a non-display area;
a display component disposed on the first substrate that displays an image;
a second substrate disposed on the display component;
a filling layer disposed between the first and second substrates; and
a sealing member positioned at edge portions of the first and second substrates that couples the first substrate and the second substrate, wherein
the filling layer comprises a first filling layer and a second filling layer, each comprising different materials, and
the second filling layer is spaced apart from the sealing member, with an empty space therebetween.

2. The display device according to claim 1, wherein each of the first and second filling layers comprises a thermoset resin comprising a filling material, a catalyst, and a cross-linking compound, or comprises an ultraviolet (UV)-curable resin.

3. The display device according to claim 2, wherein
the filling material comprises silicon (Si),
the catalyst comprises platinum (Pt), and
the cross-linking compound comprises silicon hydride (Si—H).

4. The display device according to claim 3, wherein the second filling layer has a content of greater than or equal to about 70% of the cross-linking compound of the first filling layer.

5. The display device according to claim 3, wherein the second filling layer has a content of greater than or equal to about 70% of the filling material of the first filling layer.

6. The display device according to claim 3, wherein the second filling layer has a content of greater than or equal to about 70% of the catalyst of the first filling layer.

7. The display device according to claim 1, wherein the second substrate is a glass substrate.

8. The display device according to claim 1, wherein the empty space is a vacuum or is filled with gas.

9. The display device according to claim 1, wherein the display component comprises:
a pixel circuit layer disposed on the first substrate;
a light-emitting element layer comprising a light-emitting element, which comprises a first electrode disposed on the pixel circuit layer, a light-emitting layer disposed on the first electrode, and a second electrode disposed on the light-emitting layer; and
a thin film encapsulation layer disposed between the light-emitting element layer and the filling layer.

10. A display device comprising:
a first substrate defining a display area and a non-display area;
a display component disposed on the first substrate that displays an image;
a second substrate disposed on the display component;
a filling layer disposed between the first and second substrates; and
a sealing member positioned at edge portions of the first and second substrates that couples the first substrate and the second substrate, wherein
the filling layer comprises a first filling layer and a second filling layer, each comprising a filling material, a catalyst, and a cross-linking compound,
the first filling layer and the second filling layer comprise different materials from each other, and
the second filling layer has a content of greater than or equal to about 70% of the cross-linking compound of the first filling layer.

11. The display device according to claim 10, wherein the second filling layer is spaced apart from the sealing member, with an empty space between the second filling layer and the sealing member.

12. The display device according to claim 10, wherein the first substrate and the second substrate are glass substrates.

13. A method of manufacturing a display device, the method comprising:
preparing a first mother substrate defining a display area and a non-display area;
forming a display component on a surface of the first mother substrate;
applying a sealing member on the surface of the first mother substrate along an edge;
applying a filling layer on a surface of a second mother substrate;
bonding the surface of the first mother substrate and the surface of the second mother substrate; and
separating the first and second mother substrates into display cell units, wherein
the filling layer comprises a first filling layer and a second filling layer, each comprising different materials, and
the second filling layer is spaced apart from the sealing member, with an empty space between the second filling layer and the sealing member.

14. The method according to claim 13, wherein each of the first and second filling layers comprises a thermoset resin comprising a filling material, a catalyst, and a cross-linking compound, or comprises an ultraviolet (UV)-curable resin.

15. The method according to claim 14, wherein
the filling material comprises silicon (Si),
the catalyst comprises platinum (Pt), and
the cross-linking compound comprises silicon hydride (Si—H).

16. The method according to claim 15, wherein the second filling layer has a content of greater than or equal to about 70% of the cross-linking compound of the first filling layer.

17. The method according to claim 16, wherein, when applying the filling layer on the surface of the second mother substrate, the second filling layer is applied on the surface of the second mother substrate, which overlaps an area corresponding to the display area up to about 500 μm from a boundary between the display area and the non-display area.

18. The method according to claim 13, wherein the bonding of the surface of the first mother substrate and the surface of the second mother substrate comprises irradiating a laser beam to the sealing member.

19. The method according to claim 18, further comprising curing the filling layer after the irradiating of the laser beam to the sealing member.

20. The method according to claim 13, wherein the applying of the filling layer on the surface of the second mother substrate is performed using a jet dispenser.

21. An electronic device, comprising:
a processor that provides input image data to a display device; and
the display device that displays an image based on the input image data, wherein
the display device comprises:
a first substrate defining a display area and a non-display area;
a display component disposed on the first substrate that displays an image;
a second substrate disposed on the display component;
a filling layer disposed between the first and second substrates; and
a sealing member positioned at edge portions of the first and second substrates that couples the first substrate and the second substrate, wherein
the filling layer comprises a first filling layer and a second filling layer, each comprising different materials, and
the second filling layer is spaced apart from the sealing member, with an empty space therebetween.
